(19) United States
(12) Patent Application Publication
(10) Pub. No.: US 2017/0330990 A1
(43) Pub. Date: Nov. 16, 2017

(54) METHOD FOR MANUFACTURING PHOTOVOLTAIC DEVICE

(71) Applicant: Mitsubishi Electric Corporation, Chiyoda-ku (JP)

(72) Inventors: Takehiko SATO, Tokyo (JP); Kunihiko NISHIMURA, Tokyo (JP); Shinya NISHIMURA, Tokyo (JP); Tatsuro WATAHIKI, Tokyo (JP)

(73) Assignee: Mitsubishi Electric Corporation, Chiyoda-ku (JP)

(21) Appl. No.: 15/522,458

(22) PCT Filed: May 11, 2015
(86) PCT No.: PCT/JP2015/063432

§ 371 Date: Apr. 27, 2017

(30) Foreign Application Priority Data
Dec. 17, 2014 (JP) 2014-254762

(51) Int. Cl. H01L 31/18; H01L 31/068; H01L 31/0236

(52) U.S. Cl. CPC H01L 31/18; H01L 31/02366; H01L 31/068

(57) ABSTRACT

A method for manufacturing a photovoltaic device capable of suppressing decreases in an open-circuit voltage and a fill factor or suppressing the occurrence of a current leak. The method for manufacturing a photovoltaic device includes: (a) forming a pyramidal texture on a first main surface of a silicon substrate; (b) forming a first silicate glass on the first main surface; (c) forming a second silicate glass on the first silicate glass; (d) diffusing the impurities of the first conductivity type contained in the first silicate glass to the first main surface of the silicon substrate; (e) forming a third silicate glass on the second silicate glass; and (f) diffusing impurities of a second conductivity type to a second main surface of the silicon substrate after (e).

### TECHNICAL FIELD

The present invention relates to a method for manufacturing a photovoltaic device such as a crystalline silicon solar cell, and more particularly, to a method for manufacturing a photovoltaic device that forms an impurity diffusion layer by solid phase diffusion.

### BACKGROUND ART

Crystalline silicon solar cells (hereinafter simply referred to as solar cells) are presently available in various types, and the solar cells of all types are produced in large quantities. Examples of the solar cells herein include diffusion solar cells that diffuse impurities toward a light receiving surface to form an impurity semiconductor layer, heterojunction solar cells that form an impurity semiconductor layer with a thin film such as amorphous silicon, and back-junction solar cells in which an impurity semiconductor layer of the same conductivity type as that of a substrate and an impurity semiconductor device of a conductivity type different from that of the substrate are alternately arranged in a comb-shape on the back surface of the substrate. The diffusion solar cells among the solar cells have simple manufacturing steps and thus account for most of the solar cells being currently manufactured.

The diffusion solar cell is manufactured by forming a texture that reduces reflection of light, a diffusion layer, and an antireflection layer on a crystalline silicon substrate (hereinafter simply referred to as a silicon substrate) having a thickness of about 200 μm and by forming collector electrodes such as a grid electrode and a bus electrode on the front surface and the back surface, which is a non-light receiving surface, of the silicon substrate by screen printing and then firing the silicon substrate at about 800° C. In a conventional diffusion solar cell that includes a p-type silicon substrate, a diffusion layer (back electric field layer) is formed by forming an Al electrode on the entire surface of the back surface of the silicon substrate by screen printing and by diffusing Al contained in the Al electrode to the silicon substrate. However, recombination is great in the diffusion layer formed by screen printing, so that characteristics of the diffusion solar cells fail to be greatly improved.

In contrast, solar cells having a structure that includes a passivation film formed on the back surface of the silicon substrate and an electrode locally formed on the back surface similarly to the light receiving surface have been manufactured as solar cells having higher efficiency in recent times. Not only the diffusion solar cells that include the p-type silicon substrate but also the diffusion solar cells that include an n-type silicon substrate have the above-mentioned structure. Examples of the structure include a structure in which the diffusion layer of a conductivity type different from that of the light receiving surface is formed on the entire surface of the back surface of the silicon substrate and a structure in which the diffusion layer is formed only in an electrode portion and the substrate is terminated directly by the passivation film without forming the diffusion layer in other portions. A technique for locally forming the electrode and the diffusion layer by screen printing with Al is often used for the p-type silicon substrate as in the conventional manner, instead of a technique for forming the diffusion layer on the entire surface of the back surface. In contrast, n-type impurities such as phosphorus are diffused on the entire surface of the back surface of the n-type silicon substrate since the n-type diffusion layer cannot be forming when the electrode is formed by screen printing. Therefore, the diffusion solar cell that includes the n-type silicon substrate needs a process (manufacturing step) of forming different diffusion layers on each of the front surface and the back surface.

The diffusion layer is formed by various techniques. For example, there is a technique for heat-treating a silicon substrate in an atmosphere of gas such as BBr₃ serving as p-type impurities and POCl₃ serving as n-type impurities to form a boron-silicate glass (BSG) film on one surface of the silicon substrate and a phosphosilicate glass (PSG) film on another surface and for thermally diffusing boron or phosphorus from the respective BSG film and PSG film to the silicon substrate. Alternatively, there is a technique for forming the BSG on one surface of the silicon substrate and the PSG on another surface with a source gas, which is a gas containing boron or phosphorus such as SiH₄ and B₂H₆ or SiH₄ and PH₃, by plasma chemical vapor deposition (CVD), low pressure CVD, or atmospheric pressure CVD and for subsequently heat-treating the silicon substrate at high temperature to thermally diffuse boron or phosphorus from the respective BSG film and PSG film to the silicon substrate. Alternatively, there is a technique for accelerating and implanting (injecting) ionized gas such as B+ and P+ in a substrate and then heat-treating the substrate to activate the implanted ions to form the diffusion layer.

The technique for forming the diffusion layer in the atmosphere of gas among the techniques for forming the diffusion layer described above can perform diffusion and heat treatment with one diffusion furnace, so that the diffusion layer can be formed by the simple device and process. However, the p-type impurities and the n-type impurities are diffused to both surfaces of the silicon substrate, thereby requiring masks to form the p-type diffusion layer on one surface of the silicon substrate and form the n-type diffusion layer on another surface.

The technique for forming the diffusion layer by ion implantation can easily form the diffusion layers of different conductivity types on each of the light receiving surface (front surface) and the back surface by processing each surface of the silicon substrate. However, a defect is likely to occur in the diffusion layer. Although boron is directly implanted in the silicon substrate, the front surface of the silicon substrate is exposed and thus boron is likely to pass through the front surface of the silicon substrate during heat treatment. Furthermore, boron is easily clustered during the heat treatment, and an excellent diffusion profile is hardly formed, so that it is difficult to obtain a high open-circuit voltage Voc due to recombination in the front surface of the diffusion layer (surface recombination).

The technique for forming the BSG and the PSG by CVD can form each of the BSG and the PSG on the corresponding surface of the silicon substrate, and can suppress vaporization of boron and phosphorus from the BSG and the PSG to a vapor phase by laminating thick silicon oxide on each of the BSG and the PSG. Thus, the impurities can be effectively diffused in the silicon substrate. The technique for forming the BSG and the PSG on each of the light receiving surface (front surface) and the back surface can be freely selected, and thus, for example, a process of forming the boron layer (BSG) side by CVD and forming the back surface (PSG) side by vapor-phase diffusion is conceivable. The conventional technique for forming a BSG on one surface of a silicon substrate by PECVD, forming a SiO₂ film serving as a mask on the BSG, and subsequently heat-treating the silicon substrate in an atmosphere of a source gas that contains phosphorus to collectively form the BSG on one surface and the PSG on another surface is disclosed (see Patent Document 1, for example).

### PRIOR ART DOCUMENT

### Patent Document

Patent Document 1: Japanese Unexamined Patent Application Publication (Translation of PCT Application) No. 2013-526049

### SUMMARY OF INVENTION

### Problems to be Solved by the Invention

Patent Document 1 discloses a process of performing the heat treatment in the atmosphere of the source gas after the BSG is formed by PECVD to simultaneously form the BSG and the PSG. The process is effective in simplifying the process, but a CVD film formed on the front surface of the texture, for example, becomes thin in valleys of the texture due to stress during the heat treatment, causing a difference in film thickness between valleys and peaks of the texture, or a pinhole through which the source gas is allowed to pass is formed in a SiO₂ film forming by CVD. Thus, phosphorus is diffused to the BSG through the thin film portion and the pinhole in a subsequent process of thermally diffusing phosphorus, and n+ is mixed in the p+ region to form a reverse junction, thereby decreasing an open-circuit voltage and a fill factor and causing a current leak.

The present invention has been made in view of the above mentioned problems, and an object thereof is to provide a method for manufacturing a photovoltaic device capable of suppressing decreases in an open-circuit voltage and a fill factor or suppressing the occurrence of a current leak.

### Means to Solve the Problems

To solve the problems mentioned above, a method for manufacturing a photovoltaic device according to the present invention includes the steps of: (a) forming a pyramidal texture on a first main surface of a silicon substrate; (b) forming a first silicate glass that contains impurities of a first conductivity type on the first main surface; (c) forming a second silicate glass that does not contain conductive impurities on the first silicate glass; (d) diffusing the impurities of the first conductivity type contained in the first silicate glass to the first main surface of the silicon substrate; (e) forming a third silicate glass that contains the impurities of the first conductivity type on the second silicate glass; and (f) diffusing impurities of a second conductivity type to a second main surface opposite to the first main surface of the silicon substrate after the step (e).

### Effects of the Invention

The method for manufacturing a photovoltaic device according to the present invention includes the steps of: (a) forming a pyramidal texture on a first main surface of a silicon substrate; (b) forming a first silicate glass that contains impurities of a first conductivity type on the first main surface; (c) forming a second silicate glass that does not contain conductive impurities on the first silicate glass; (d) diffusing the impurities of the first conductivity type contained in the first silicate glass to the first main surface of the silicon substrate; (e) forming a third silicate glass that contains the impurities of the first conductivity type on the second silicate glass; and (f) diffusing impurities of a second conductivity type to a second main surface opposite to the first main surface of the silicon substrate after the step (e). Therefore, the decreases in the open-circuit voltage and the fill factor or the occurrence of the current leak can be suppressed.

These and other objects, features, aspects and advantages of the present technology will become more apparent from the following detailed description of the present technology when taken in conjunction with the accompanying drawings.

### BRIEF DESCRIPTION OF DRAWINGS

FIG. 1 is a cross-sectional view showing an example of a configuration of a photovoltaic device according to a first embodiment of the present invention.

FIG. 2 is a flowchart showing an example of a method for manufacturing a photovoltaic device according to the first embodiment of the present invention.

FIG. 3 shows an example of the method for manufacturing a photovoltaic device according to the first embodiment of the present invention.

FIG. 4 shows an example of the method for manufacturing a photovoltaic device according to the first embodiment of the present invention.

FIG. 5 shows an example of the method for manufacturing a photovoltaic device according to the first embodiment of the present invention.

FIG. 6 shows an example of the method for manufacturing a photovoltaic device according to the first embodiment of the present invention.

FIG. 7 shows an example of the method for manufacturing a photovoltaic device according to the first embodiment of the present invention.

FIG. 8 shows an example of the method for manufacturing a photovoltaic device according to the first embodiment of the present invention.

FIG. 9 shows an example of the method for manufacturing a photovoltaic device according to the first embodiment of the present invention.

FIG. 10 is a cross-sectional view of a photovoltaic device according to a first comparative example.

FIG. 11 is a cross-sectional view of the photovoltaic device according to the first embodiment of the present invention.

FIG. 12 is a flowchart showing an example of a method for manufacturing a photovoltaic device according to a second embodiment of the present invention.

FIG. 13 is flowchart showing an example of a method for manufacturing a photovoltaic device according to a third embodiment of the present invention.

FIG. 14 shows an example of the method for manufacturing a photovoltaic device according to the third embodiment of the present invention.

FIG. 15 is a cross-sectional view showing an example of a configuration of a photovoltaic device according to a fifth embodiment of the present invention.

FIG. 16 is a flowchart showing an example of a method for manufacturing a photovoltaic device according to the fifth embodiment of the present invention.

FIG. 17 shows an example of the method for manufacturing a photovoltaic device according to the fifth embodiment of the present invention.

FIG. 18 shows an example of the method for manufacturing a photovoltaic device according to the fifth embodiment of the present invention.

FIG. 19 shows an example of the method for manufacturing a photovoltaic device according to the fifth embodiment of the present invention.

FIG. 20 shows an example of the method for manufacturing a photovoltaic device according to the fifth embodiment of the present invention.

FIG. 21 shows an example of the method for manufacturing a photovoltaic device according to the fifth embodiment of the present invention.

FIG. 22 shows an example of the method for manufacturing a photovoltaic device according to the fifth embodiment of the present invention.

FIG. 23 shows an example of the method for manufacturing a photovoltaic device according to the fifth embodiment of the present invention.

### DESCRIPTION OF EMBODIMENTS

Hereinafter, embodiments are described with reference to the accompanying diagrams.

### First Embodiment

First, a configuration of a photovoltaic device according to a first embodiment of the present invention will be described. The first embodiment gives description, assuming that the photovoltaic device is a photovoltaic cell.

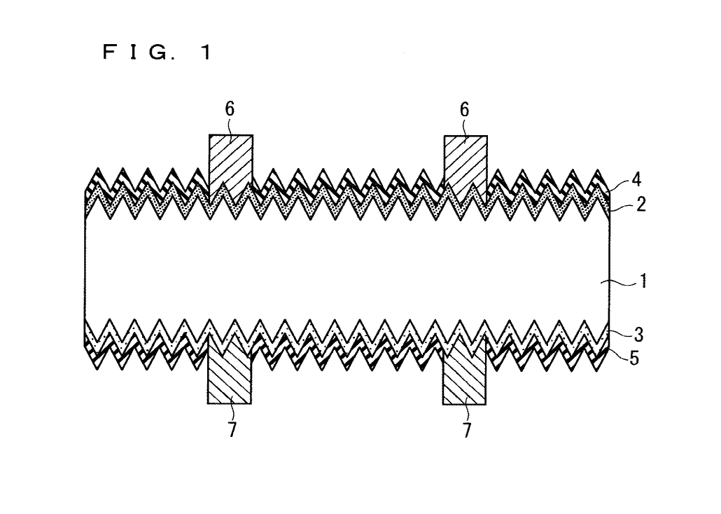

FIG. 1 is a cross-sectional view showing an example of a configuration of the photovoltaic device according to the first embodiment.

As shown in FIG. 1, the photovoltaic device has a texture formed on a first main surface (upper surface of the paper plane) and a second main surface (lower surface of the paper plane). A first passivation film 4 laminated and formed on a first diffusion layer 2 that contains p-type impurities (impurities of a first conductivity type) is laminated and formed on the first main surface. A first electrode 6 is formed so as to penetrate the first passivation film 4 and contact the first diffusion layer 2.

On the other hand, a second passivation film 5 laminated and formed on a second diffusion layer 3 that contains n-type impurities (impurities of a second conductivity type) is laminated and formed on the second main surface. A second electrode 7 is formed so as to penetrate the second passivation film 5 and contact the second diffusion layer 3.

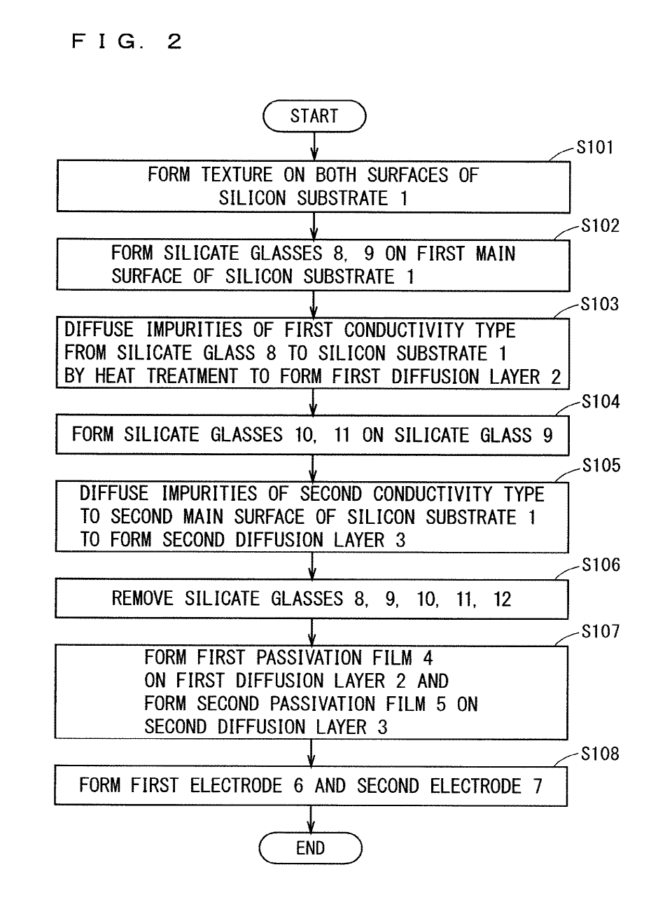

Next, a method for manufacturing a photovoltaic device will be described with reference to FIGS. 2 to 10.

FIG. 2 is a flowchart showing an example of the method for manufacturing a photovoltaic device. FIGS. 3 to 10 show examples of steps of manufacturing a photovoltaic device.

In Step S101, as shown in FIG. 3, a texture is formed on both surfaces of a silicon substrate 1. Specifically, the silicon substrate 1 is immersed in an alkaline solution to remove damage occurring when being sliced by a wire saw. The silicon substrate 1 is then immersed in the alkaline solution to which isopropyl alcohol is added to form the pyramidal texture on both the surfaces (the first main surface and the second main surface) of the silicon substrate 1.

The silicon substrate 1, which is made of n-type monocrystals, is assumed to have 156 mm□ (a square having a side of 156 mm), have a resistivity of 1 μcm, and have a thickness of about 200 μm.

Although the first embodiment describes the case where the texture is formed on both the surfaces of the silicon substrate 1, it suffices that the texture is formed on at least a surface on which light is incident, and thus the texture may be formed on only one surface.

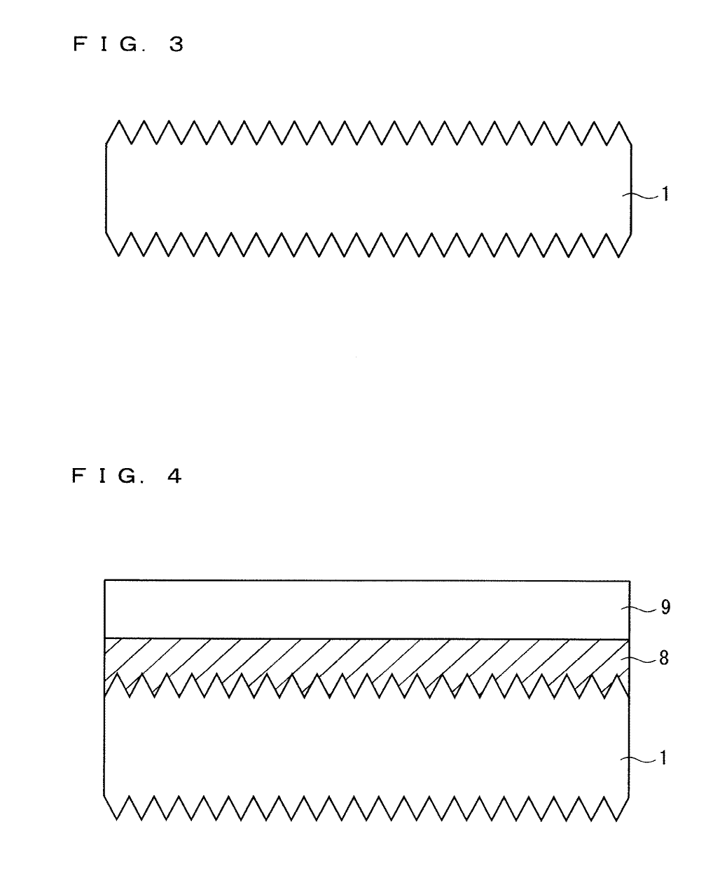

In Step S102, as shown in FIG. 4, a silicate glass 8 (first silicate glass) that contains boron (impurities of the first conductivity type) is laminated and formed on the first main surface of the silicon substrate 1 by atmospheric pressure CVD, and a silicate glass 9 (second silicate glass) that does not contain impurities imparting conductivity is laminated and formed on the silicate glass 8. Herein, examples of the impurities imparting conductivity include group III or V boron, phosphorus, gallium, and arsenic if the impurities are silicon being semiconductor of a group IV element. The expression “the silicate glass 9 does not contain the impurities” indicates that the impurities imparting conductivity contained in the silicate glass 9 are sufficiently smaller in amount than the amount of the impurities diffused from the silicate glass 8 after heat treatment in following steps and are small enough to substantially have no influence on the diffusion layer 2 or the diffusion layer 3 formed in the following steps. The expression does not necessarily indicate that the silicate glass 9 contains no impurity at all.

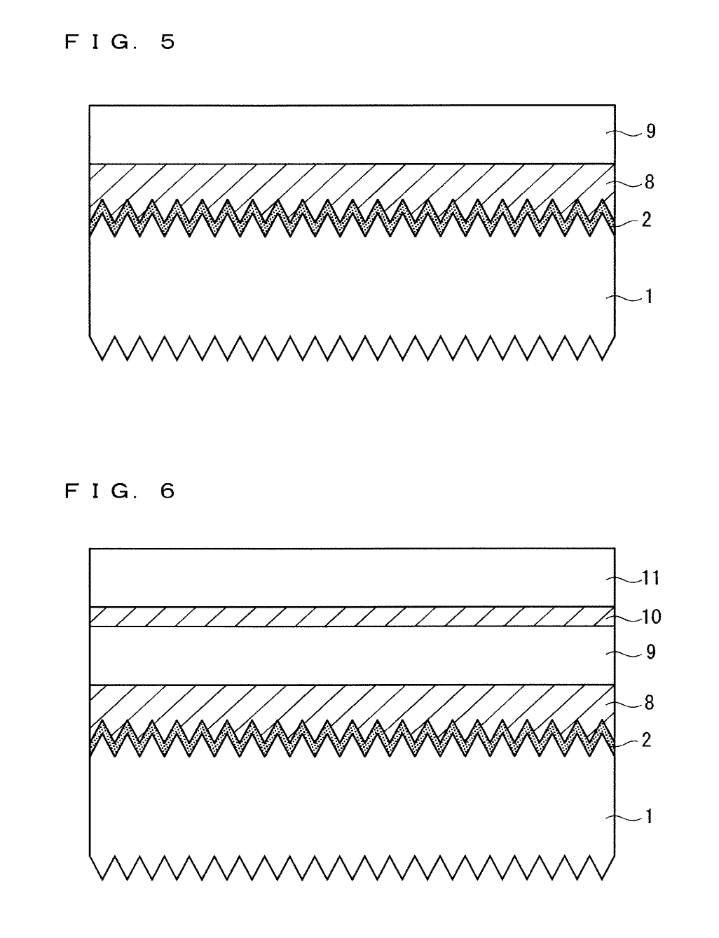

In Step S103, as shown in FIG. 5, the silicon substrate 1 after Step S102 is annealed (heat-treated) in an atmosphere at about 1000° C. to diffuse boron from the silicate glass 8 to the first main surface of the silicon substrate 1, to thereby form the first diffusion layer 2.

In Step S104, as shown in FIG. 6, a silicate glass 10 (third silicate glass) that contains boron (impurities of the first conductivity type) is formed on the silicate glass 9, and a silicate glass 11 (fourth silicate glass) that does not contain impurities imparting conductivity is formed over the silicate glass 9.

The silicate glass 11 is formed for preventing boron from vaporizing from the silicate glass 10 into the atmosphere and from adhering to the second main surface. However, if the amount of vaporization of boron is small depending on the condition of the silicate glass 10 or characteristics of the photovoltaic device do not deteriorate due to boron adhering to the second main surface, the formation of the silicate glass 11 may be omitted.

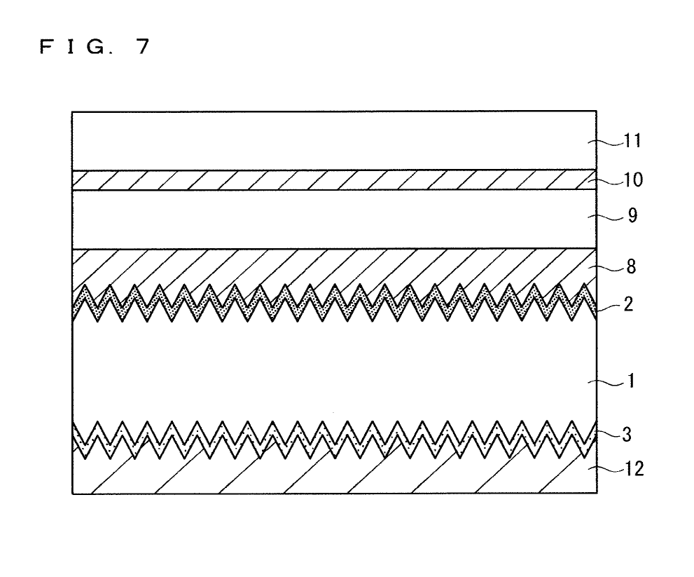

In Step S105, as shown in FIG. 7, phosphorus (impurities of the second conductivity type) is diffused to the second main surface of the silicon substrate 1 to form the second diffusion layer 3 and a silicate glass 12. Specifically, POCl₃ volatilizes by bubbling, and the silicon substrate 1 after Step S104 is heated in a furnace, to thereby form the silicate glass 12 on the second main surface and form the second diffusion layer 3 on the second main surface.

The technique for forming the second diffusion layer 3 by bubbling is a typical technique for forming an n-type diffusion layer and enables the formation at low cost, but the silicate glass 12 is formed on both the surfaces of the silicon substrate 1, which requires a mask film to be previously formed on the first main surface side where the silicate glass 12 is not formed. In the first embodiment, the silicate glasses 8 to 11 function as mask films that prevent phosphorus to be diffused to the first main surface of the silicon substrate 1.

In Step S106, as shown in FIG. 8, the silicate glasses 8, 9, 10, 11, 12 are removed. Specifically, the silicon substrate 1 after Step S105 is immersed in a solution of hydrofluoric acid of about 10% to remove the silicate glasses 8, 9, 10, 11, 12.

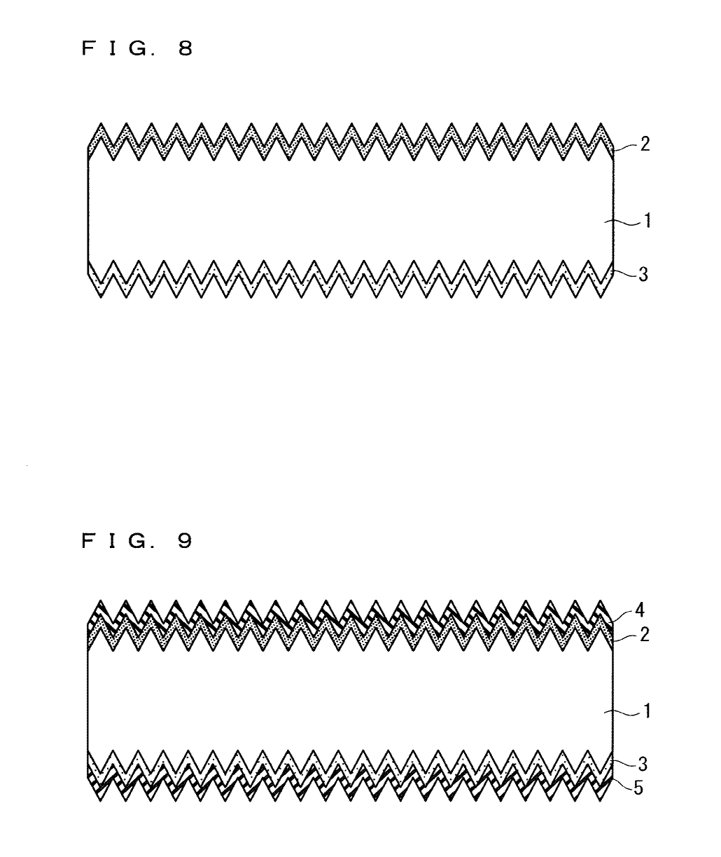

In Step S107, as shown in FIG. 9, the first passivation film 4 is formed on the first diffusion layer 2, and the second passivation film 5 is formed on the second diffusion layer 3. Specifically, the silicon substrate 1 after Step S106 is annealed (heat-treated) in an atmosphere of oxygen, to thereby form the first passivation film 4 on the first diffusion layer 2 by thermal oxidation and form the second passivation film 5 on the second diffusion layer 3 by thermal oxidation.

Subsequently, a silicon nitride film (not shown) serving as an antireflection film is formed on each of the first passivation film 4 and the second passivation film 5 by plasma CVD.

In Step S108, both the surfaces of the silicon substrate 1 shown in FIG. 9 are printed with printing paste that contains Ag as a main component and then fired, to thereby form collector electrodes (the first electrode 6 and the second electrode 7) formed of a grid electrode and a bus electrode. Consequently, the photovoltaic device as shown in FIG. 1 is manufactured.

Next, effects of the photovoltaic device according to the first embodiment will be described.

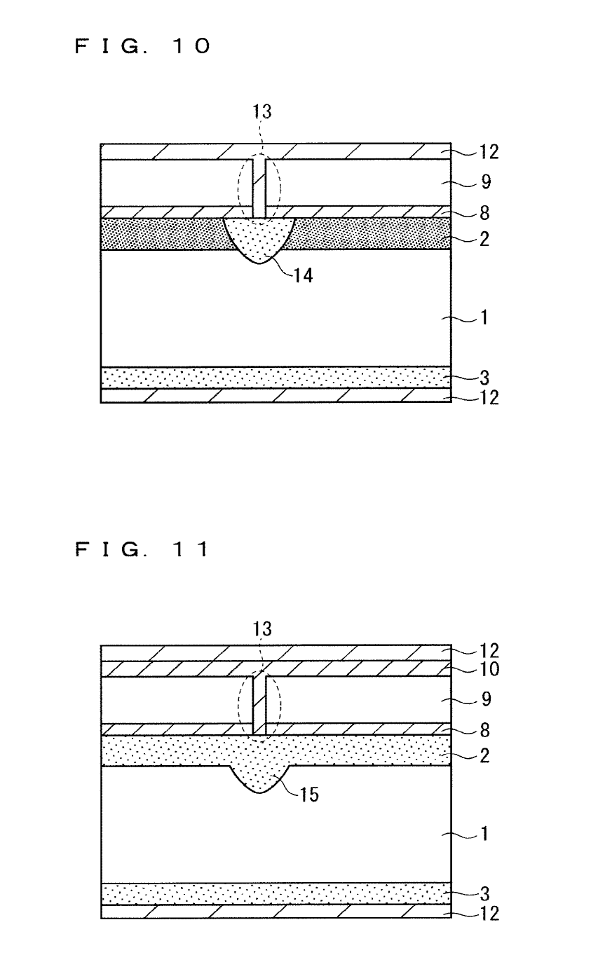

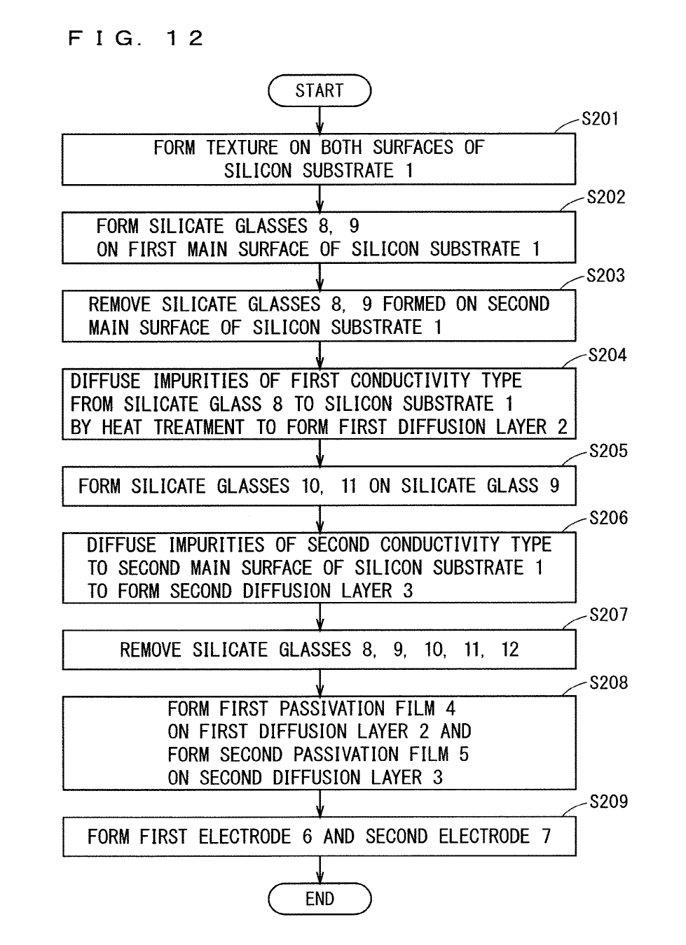

FIG. 10 is a cross-sectional view of a photovoltaic device according to a first comparative example and shows a step of manufacturing a photovoltaic device. It is assumed that the silicon substrate 1 has the texture on both the surfaces although the illustration is omitted from FIG. 10 for the sake of simplicity. The first comparative example is a diagram used for describing the effects of the first embodiment shown in FIG. 11 described below.

The silicate glasses 10, 11 are not formed in the photovoltaic device according to the first comparative example in its manufacturing step. It is assumed that the silicate glasses 8, 9 have a defect portion 13 (non-formation portion of the silicate glasses 8, 9, such as a pinhole) formed therein.

As shown in FIG. 10, when phosphorus (impurities of the second conductivity type) is diffused to the second main surface of the silicon substrate 1 to form the second diffusion layer 3, phosphorus is diffused to the first diffusion layer 2 through the defect portion 13 formed on the first main surface side of the silicon substrate 1 to form an impurity diffusion layer 14 in the first diffusion layer 2 and the defect portion 13 (at this time, the silicate glass 12 is formed on the silicate glass 9). The amount of diffusion of phosphorus into the first diffusion layer 2 reaching the amount that cannot be ignored for the impurity concentration in the first diffusion layer 2 may cause decreases in open-circuit voltage and fill factor and cause a current leak in a case where a reverse bias is applied.

The defect portion 13 generated in the silicate glass 9 may occur due to an influence of particles or the like when the silicate glasses 8, 9 are formed or due to film stress in heat treatment when the first diffusion layer 2 is formed. For the pyramidal texture formed in the solar cell, the silicate glass is thin especially at the bottom of the pyramidal texture, resulting in deteriorating characteristics.

Although the impurity concentration in the impurity diffusion layer 14 (concentration of phosphorus in the example of FIG. 10) that affects the characteristics of the photovoltaic device depends on the impurity content of the silicate glasses 8, 9 and the subsequent annealing condition, the deteriorating characteristics or the current leak occurs when the impurity diffusion layer 14 to be eventually formed has a sheet resistance of less than or equal to three times a sheet resistance of the first diffusion layer 2, for example, when the impurity diffusion layer 14 has a sheet resistance of less than or equal to 300Ω/□ at a sheet resistance of 100Ω/□ of the first diffusion layer 2.

FIG. 11 is a cross-sectional view of the photovoltaic device according to the first embodiment and shows a step of manufacturing a photovoltaic device. It is assumed that the silicon substrate 1 has the texture on both the surfaces although the illustration is omitted from FIG. 11 for the sake of simplicity. It is also assumed that the silicate glass 11 is not formed.

As shown in FIG. 11, heat treatment is performed to form the first diffusion layer 2 after the silicate glasses 8, 9 are formed. As described above, the defect portion 13 is generated in the silicate glasses 8, 9 due to stress at the time of formation of the silicate glasses 8, 9 or the heat treatment. For the photovoltaic device according to the first embodiment, the silicate glass 10 is formed after the heat treatment. Thus, when the second diffusion layer 3 is subsequently formed, the silicate glass 10 can prevent phosphorus (impurities of the second conductivity type) from entering the defect portion 13. An impurity-concentration increasing portion 15 is formed in the first diffusion layer 2 and the defect portion 13 by the heat treatment for forming the second diffusion layer 3, so that a deterioration of the characteristics in the defect portion 13 can be suppressed.

Specifically, the defect portion 13 sometimes causes the deterioration of the characteristics since the particles causing the defect portion 13 and metal impurities adhering after the formation of the silicate glasses 8, 9 are diffused in the subsequent steps to cause a deteriorating condition of the interface between the first diffusion layer 2 and the silicon substrate 1. For the photovoltaic device according to the first embodiment, the impurity-concentration increasing portion 15 is formed to increase a field effect of the first diffusion layer 2 in order to prevent carriers in the silicon substrate 1 from moving closer to the defect portion 13, so that recombination of the carriers can be suppressed at the portion where the condition of the interface between the first diffusion layer 2 and the silicon substrate 1 deteriorates.

As a result of evaluating current-voltage characteristics in each of the photovoltaic device (see FIG. 10) according to the first comparative example and the photovoltaic device (see FIG. 11) according to the first embodiment under AM 1.5 light illumination, the first embodiment has an open-circuit voltage of 2 mV higher and an fill factor of 0.005 higher than those of the first comparative example. The first comparative example has a current (leak current) of 1.0 A flowing in a direction opposite to the current-voltage characteristics during the application of a voltage of 10 V while the first embodiment has the current of 0.2 A, which shows a tendency of improvement.

As described above, the first embodiment can suppress the decreases in the open-circuit voltage and the fill factor or the occurrence of the current leak.

### Second Embodiment

In Step S102 (corresponding to FIG. 4) in FIG. 2, the silicate glasses 8, 9 when being formed on the first main surface of the silicon substrate 1 flow toward the second main surface of the silicon substrate 1 and are formed thereon. A second embodiment of the present invention is characterized such that the silicate glasses 8, 9 formed on the second main surface of the silicon substrate 1 are removed. The manufacturing method other than this is the same as that in the first embodiment, so that the description is omitted here.

FIG. 12 is a flowchart showing an example of a method for manufacturing a photovoltaic device according to the second embodiment. Steps S201, S202, S204 to S209 in FIG. 12 respectively correspond to Steps S101 to S108 in FIG. 2, so that the description is omitted here. Step S203 will be described below.

In Step S203, the silicon substrate 1 after Step S202 is immersed in 1% hydrofluoric acid to remove the silicate glasses 8, 9 formed on the second main surface of the silicon substrate 1.

The silicate glasses 8, 9 formed on the second main surface of the silicon substrate 1 serve as masks themselves and prevent the second diffusion layer 3 from being formed subsequently. The silicate glasses 8, 9 cause the first impurities (boron herein) to be diffused to the second main surface of the silicon substrate 1 and cause the deteriorating characteristics due to the heat treatment for forming the second diffusion layer 3. Thus, the silicate glasses 8, 9 formed on the second main surface of the silicon substrate 1 are preferably processed (removed) with the hydrofluoric acid. However, if the whole silicon substrate 1 is immersed in the hydrofluoric acid to remove the silicate glasses 8, 9 formed on the second main surface, the silicate glass 9 formed on the first main surface side becomes thinner, thereby making an already existed defect portion larger or generating a new defect portion. The bottom of the texture formed on both the surfaces of the silicon substrate 1 is especially thin due to the stress by annealing, so that the bottom is easily melted by the hydrofluoric acid to have a defect portion formed therein. To solve such a problem, the silicate glass 10 is formed on the silicate glass 9 formed on the first main surface side of the silicon substrate 1 (Step S205) after Step S203 in the second embodiment, so that the silicate glass 10 can complement the silicate glass 9 whose film thickness has been reduced in Step S203 on the first main surface side.

As a result of evaluating the current-voltage characteristics under AM 1.5 light illumination in a case where a photovoltaic device manufactured without forming the silicate glasses 10, 11 (without performing Step S205) in FIG. 12 is assumed as a second comparative example, the photovoltaic device in the second embodiment has an open-circuit voltage of 4 mV higher and an fill factor of 0.008 higher than those of the second comparative example. The second comparative example has a current (leak current) of 2.0 A flowing in a direction opposite to the current-voltage characteristics during the application of a voltage of 10 V while the second embodiment has the current of 0.2 A, which shows a tendency of improvement.

The leak current is most likely to be generated at the p-n junction and rapidly increases when a region of a conductivity type reverse to a conductivity type of an emitter is formed in an emitter diffusion layer. Thus, if the diffusion layer of the conductivity type different from that of the substrate is formed on the surface of the substrate as in this application and a defect portion may be generated in a mask film of the diffusion layer, a reverse junction is formed at the p-n junction portion, causing a large amount of leak current and deteriorating characteristics. In contrast, the diffusion layer of the reverse conductivity type has a relatively small influence on the diffusion layer of the same conductivity type as the conductivity type of the substrate.

As described above, the second embodiment can suppress the decreases in the open-circuit voltage and the fill factor or the occurrence of the current leak.

### Third Embodiment

The case in which the silicate glass 10 is formed after the first diffusion layer 2 is formed is described in the first and second embodiments. A third embodiment of the present invention is characterized such that the silicate glass 10 is formed before the first diffusion layer 2 is formed. The manufacturing method other than this is the same as that in the second embodiment, so that the description is omitted here.

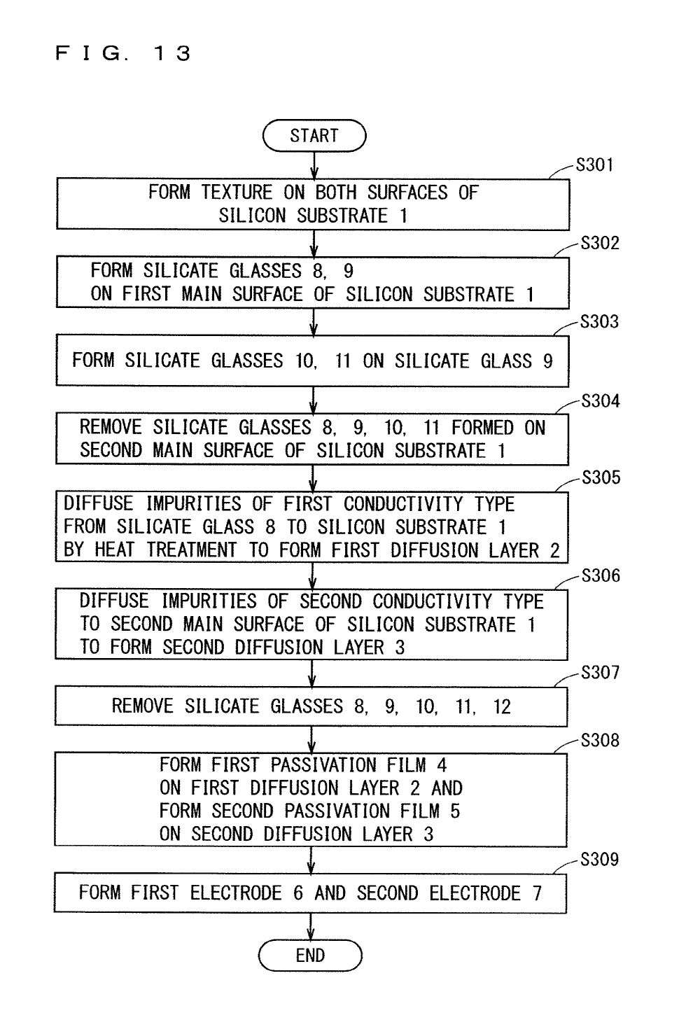

FIG. 13 is a flowchart showing an example of a method for manufacturing a photovoltaic device according to the third embodiment. Steps S301, S302, S307 to S309 in FIG. 13 respectively correspond to Steps S201, S202, S207 to S209 in FIG. 2, so that the description is omitted here. Steps S303 to S306 will be described below.

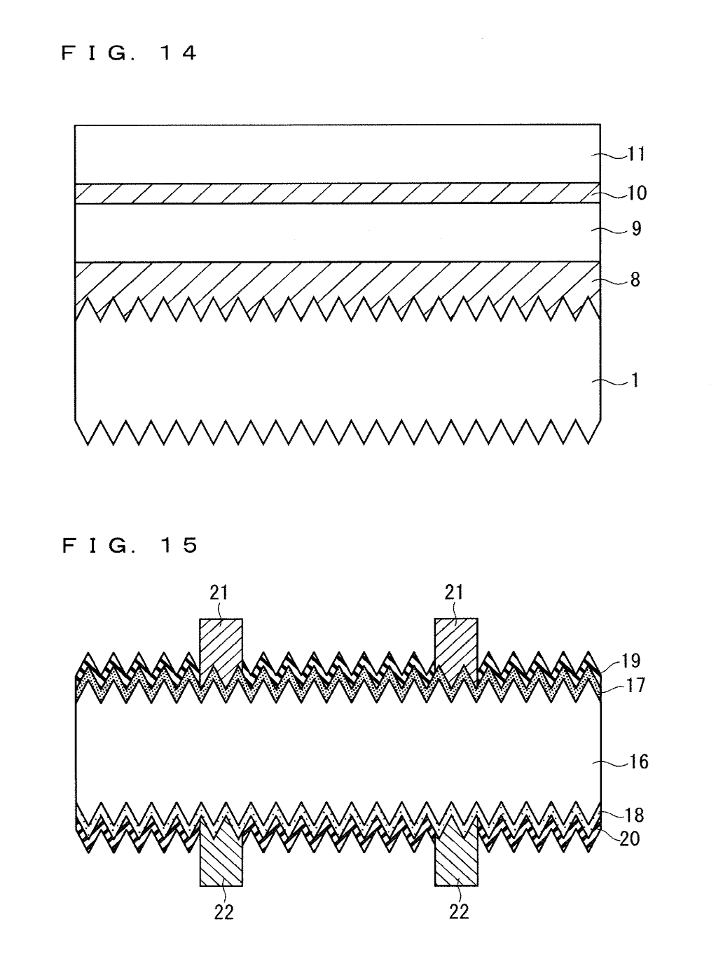

In Step S303, as shown in FIG. 14, the silicate glass 10 is formed on the silicate glass 9, and the silicate glass 11 is formed over the silicate glass 9. Specifically, the silicate glass 10 and the silicate glass 11 are formed by sputtering.

Sputtering is less likely to have an influence of stress due to heating than atmospheric pressure CVD and is capable of forming a thick film at the bottom of the texture depending on the condition of deposition. Therefore, sputtering causes a smaller amount of the silicate glass 10 and the silicate glass 11 to flow toward the second main surface side than atmospheric pressure CVD does in addition to being capable of forming the silicate glass 10 and the silicate glass 11 before the formation (before the heat treatment) of the first diffusion layer 2. Thus, at the time of subsequent processing with the hydrofluoric acid, the silicate glasses 8, 9, 10, 11 formed on the second main surface side can be removed while the first main surface is protected, so that a defect portion is less likely to be generated.

In Step S304, the silicon substrate 1 after Step S303 is immersed in 1% hydrofluoric acid to remove the silicate glasses 8, 9, 10, 11 formed on the second main surface of the silicon substrate 1.

In Step S305, the silicon substrate 1 after Step S304 is annealed in an atmosphere at about 1000° C. to diffuse boron from the silicate glass 8 to the first main surface of the silicon substrate 1, to thereby form the first diffusion layer 2.

In Step S306, phosphorus (impurities of the second conductivity type) is diffused to the second main surface of the silicon substrate 1 to form the second diffusion layer 3 and the silicate glass 12.

As a result of evaluating the current-voltage characteristics under AM 1.5 light illumination in a case where a photovoltaic device manufactured without forming the silicate glasses 10, 11 (without performing Step S303) in FIG. 13 is assumed as a third comparative example, the photovoltaic device in the third embodiment has an open-circuit voltage of 5 mV higher and an fill factor of 0.01 higher than those of the third comparative example. The third comparative example has a current (leak current) of 2.0 A flowing in a direction opposite to the current-voltage characteristics during the application of a voltage of 10 V while the third embodiment has the current of 0.2 A, which shows a tendency of improvement.

As described above, the third embodiment can suppress the decreases in the open-circuit voltage and the fill factor or the occurrence of the current leak.

The application of the third embodiment to the second embodiment is described above, which is not restrictive, and the third embodiment may be applied to the first embodiment.

### Fourth Embodiment

A fourth embodiment of the present invention is characterized such that the silicate glasses 10, 11 are formed partially by coating. The manufacturing method other than this is the same as that in the first embodiment, so that the description is omitted here.

For example, in Step S104 in FIG. 2, the silicate glasses 10, 11 are formed only at the end portion of the silicon substrate 1, and preferably formed only at a portion at an interval of about 5 mm from the end portion by coating with an ink jet.

Here, a photovoltaic device manufactured without performing coating with the ink jet, which corresponds to Step S104, similarly to the first embodiment is assumed as a fourth comparative example. The fourth comparative example has the same process as that of the first comparative example in the first embodiment, and also has the same current-voltage characteristics and current leak characteristics as those of the first comparative example. As a result, the fourth embodiment has an open-circuit voltage of 2 mV higher and a fill factor of 0.05 higher than those of the fourth comparative example. The fourth comparative example has a current (leak current) of 1.0 A flowing in a direction opposite to the current-voltage characteristics during the application of a voltage of 10 V while the fourth embodiment has the current of 0.3 A, which shows a tendency of improvement even with the smaller effect of improvement compared to the first embodiment. This indicates that the portions having deteriorating characteristics concentrate at the interval of 5 mm from the end portion of the silicon substrate 1. In other words, the fourth embodiment obtains the same effects as those of the first embodiment by using a simple process of coating.

As described above, the fourth embodiment can suppress the decreases in the open-circuit voltage and the fill factor or the occurrence of the current leak.

The application of the fourth embodiment to the second embodiment is described above, which is not restrictive, and the fourth embodiment may be applied to the second embodiment.

### Fifth Embodiment

First, a configuration of a photovoltaic device according to a fifth embodiment of the present invention will be described. The fifth embodiment gives description, assuming that the photovoltaic device is a photovoltaic cell.

FIG. 15 is a cross-sectional view showing an example of the configuration of the photovoltaic device according to the fifth embodiment.

As shown in FIG. 15, the photovoltaic device has a texture formed on a first main surface (upper surface of the paper plane) and a second main surface (lower surface of the paper plane). A first passivation film 19 laminated and forming on a first diffusion layer 17 that contains n-type impurities (impurities of a first conductivity type) is laminated and formed on the first main surface. A first electrode 21 is formed so as to penetrate the first passivation film 19 and contact the first diffusion layer 17.

On the other hand, a second passivation film 20 laminated and formed on a second diffusion layer 18 that contains p-type impurities (impurities of a second conductivity type) is laminated and formed on the second main surface. A second electrode 22 is formed so as to penetrate the second passivation film 20 and contact the second diffusion layer 18.

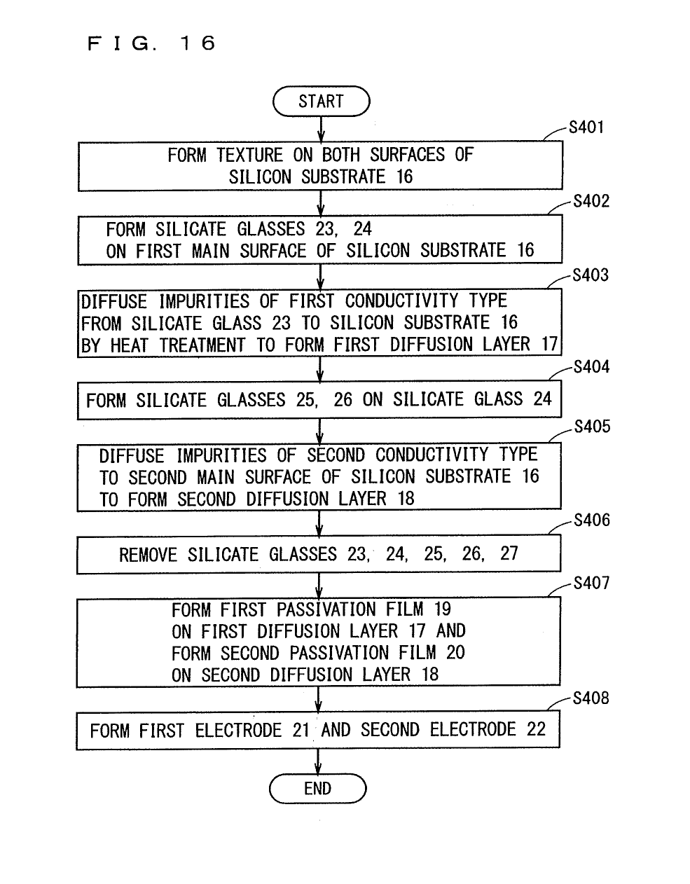

Next, a method for manufacturing a photovoltaic device will be described with reference to FIGS. 16 to 23.

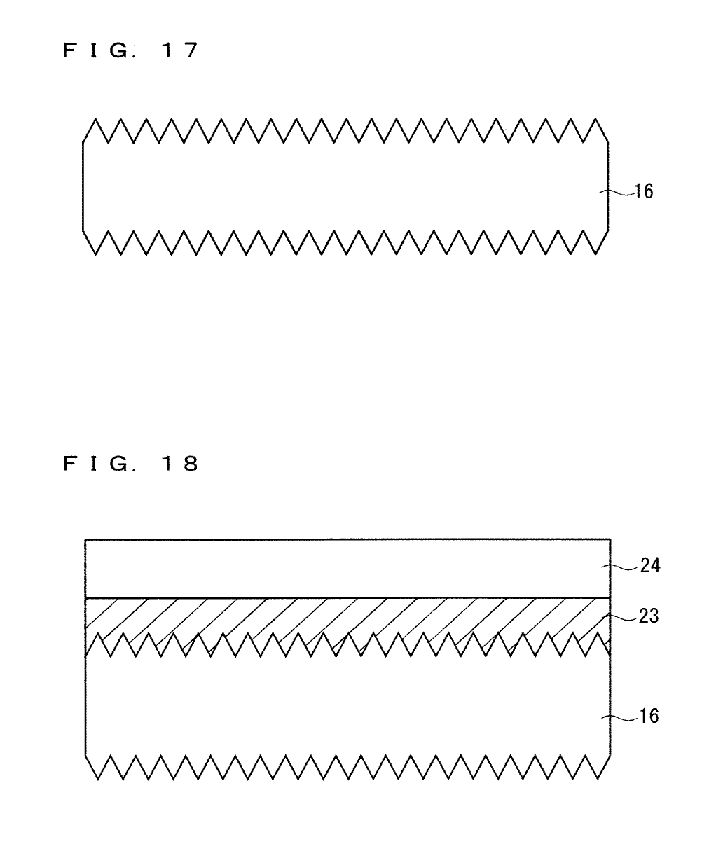

FIG. 16 is a flowchart showing an example of the method for manufacturing a photovoltaic device. FIGS. 17 to 23 show examples of steps of manufacturing a photovoltaic device.

In Step S401, as shown in FIG. 17, a texture is formed on both surfaces of a silicon substrate 16. Specifically, the silicon substrate 16 is immersed in an alkaline solution to remove damage occurring when being sliced by a wire saw. The pyramidal texture is then formed on both the surfaces (the first main surface and the second main surface) of the silicon substrate 16 by immersing the silicon substrate 16 in the alkaline solution to which isopropyl alcohol is added.

The silicon substrate 16, which is made of p-type monocrystals, is assumed to have 156 mm□ (a square having a side of 156 mm), have a resistivity of 1 Ωcm, and have a thickness of about 200 μm.

Although the fifth embodiment describes the case where the texture is formed on both the surfaces of the silicon substrate 16, it suffices that the texture is formed on at least a surface on which light is incident, and thus the texture may be formed on only one surface.

In Step S402, as shown in FIG. 18, a silicate glass 23 (first silicate glass) that contains phosphorus (impurities of the first conductivity type) is laminated and formed on the first main surface of the silicon substrate 16 by atmospheric pressure CVD, and a silicate glass 24 (second silicate glass) that does not contain impurities imparting conductivity is laminated and formed on the silicate glass 23.

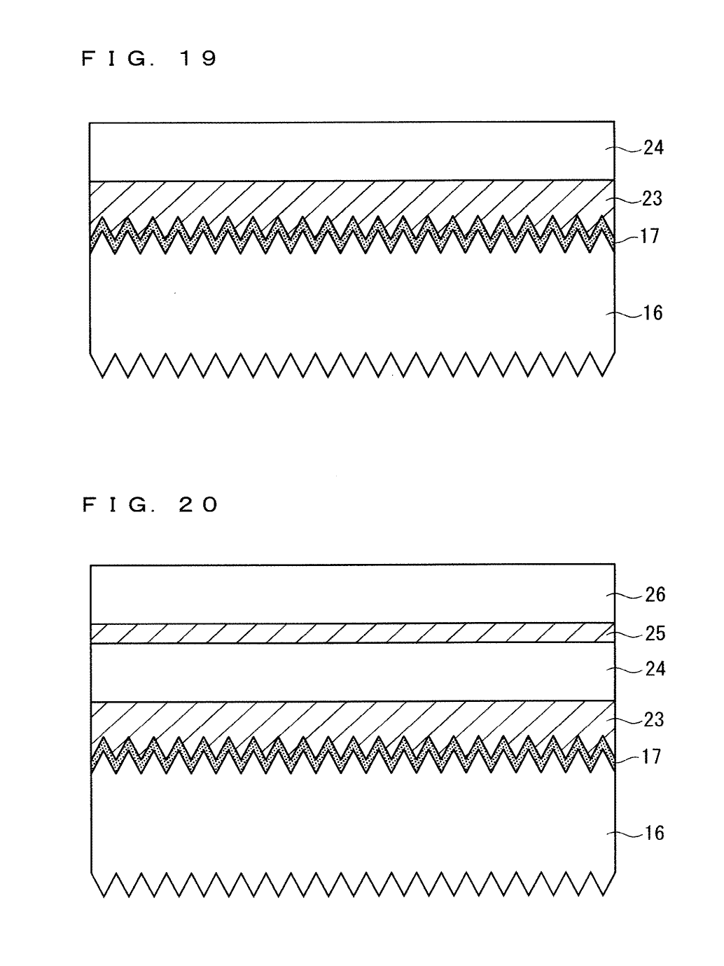

In Step S403, as shown in FIG. 19, the silicon substrate 16 after Step S402 is annealed (heat-treated) in an atmosphere at about 900° C. to diffuse phosphorus from the silicate glass 23 to the first main surface of the silicon substrate 16, to thereby form the first diffusion layer 17.

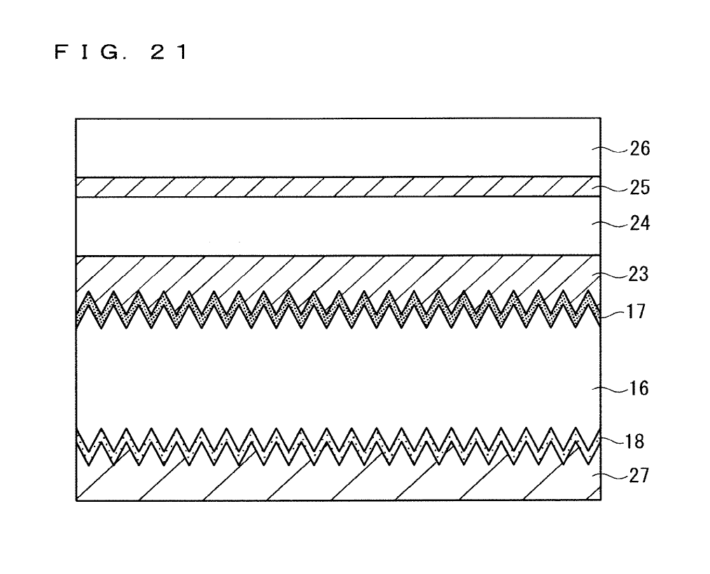

In Step S404, as shown in FIG. 20, a silicate glass 25 (third silicate glass) that contains phosphorus (impurities of the first conductivity type) is forming on the silicate glass 24, and a silicate glass 26 (fourth silicate glass) that does not contain impurities imparting conductivity is formed over the silicate glass 24.

The silicate glass 26 is formed for preventing phosphorus from vaporizing from the silicate glass 25 into the atmosphere and from adhering to the second main surface. However, if the amount of vaporization of phosphorus is small depending on the condition of the silicate glass 25 or characteristics of the photovoltaic device do not deteriorate due to phosphorus adhering to the second main surface, the formation of the silicate glass 26 may be omitted.

In Step 405, as shown in FIG. 21, boron (impurities of the second conductivity type) is diffused to the second main surface of the silicon substrate 16 to form the second diffusion layer 18 and the silicate glass 27. Specifically, boron bromide (BBr₃) volatilizes by bubbling, and the silicon substrate 16 after Step S404 is heated in a furnace, to thereby form the silicate glass 27 on the second main surface and form the second diffusion layer 18 on the second main surface.

The technique for forming the second diffusion layer 18 by bubbling is a typical technique for forming a p-type diffusion layer and enables the formation at low cost, but the silicate glass 27 is formed on both the surfaces of the silicon substrate 16, which requires a mask film to be previously formed on the first main surface side where the silicate glass 27 is not formed. In the fifth embodiment, the silicate glasses 23 to 26 function as mask films that prevent boron to be diffused to the first main surface of the silicon substrate 16.

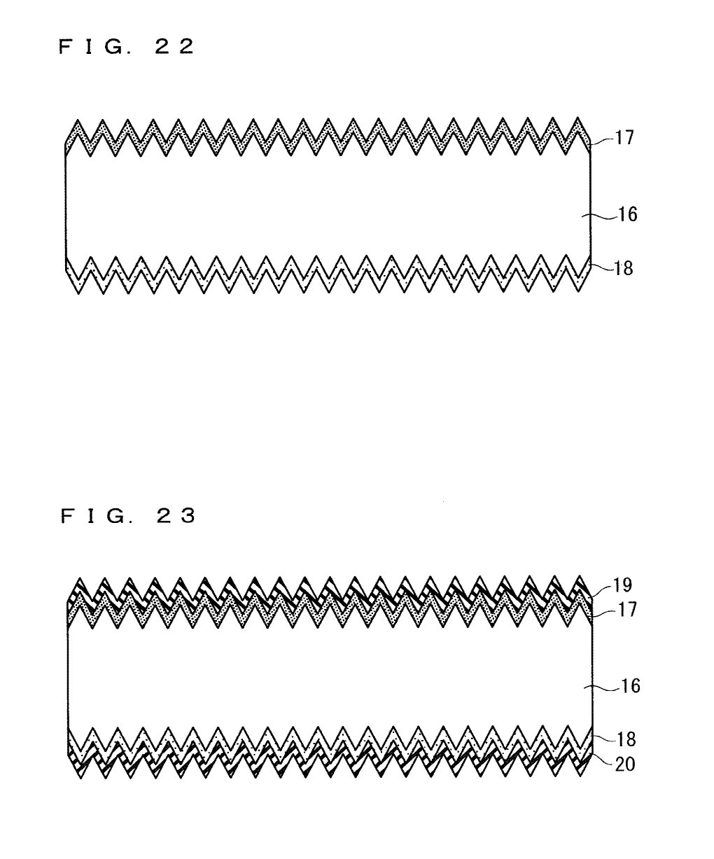

In Step S406, as shown in FIG. 22, the silicate glasses 23, 24, 25, 26, 27 are removed. Specifically, the silicon substrate 16 after Step S405 is immersed in a solution of hydrofluoric acid of about 10% to remove the silicate glasses 23, 24, 25, 26, 27.

In Step S407, as shown in FIG. 23, the first passivation film 19 is formed on the first diffusion layer 17, and the second passivation film 20 is formed on the second diffusion layer 18. Specifically, the silicon substrate 16 after Step S406 is annealed (heat-treated) in an atmosphere of oxygen, to thereby form the first passivation film 19 on the first diffusion layer 17 by thermal oxidation and form the second passivation film 20 on the second diffusion layer 18 by thermal oxidation.

Subsequently, a silicon nitride film (not shown) serving as an antireflection film is formed on each of the first passivation film 19 and the second passivation film 20 by plasma CVD.

In Step S408, both the surfaces of the silicon substrate 16 shown in FIG. 23 are printed with printing paste that contains Ag as a main component and then fired, to thereby form collector electrodes (the first electrode 21 and the second electrode 22) formed of a grid electrode and a bus electrode. Consequently, the photovoltaic device as shown in FIG. 15 is manufactured.

Next, effects of the photovoltaic device according to the fifth embodiment will be described with reference to a fifth comparative example.

The silicate glasses 25, 26 are not formed in the photovoltaic device according to the fifth comparative example in its manufacturing step. The other manufacturing steps are the same as those of the fifth embodiment. A section of the photovoltaic device according to the fifth comparative example is the same as FIG. 10. The silicon substrate 1, the first diffusion layer 2, the second diffusion layer 3, and the silicate glasses 8, 9, 12 in FIG. 10 respectively correspond to the silicon substrate 16, the first diffusion layer 17, the second diffusion layer 18, and the silicate glasses 23, 24, 27 in the fifth comparative example. With reference to FIG. 10, it is assumed that the silicate glasses 23, 24 in the photovoltaic device according to the fifth comparative example have a defect portion (non-formation portion of the silicate glasses 23, 24, such as a pinhole) formed therein.

A section of the photovoltaic device according to the fifth embodiment is the same as FIG. 11. The silicon substrate 1, the first diffusion layer 2, the second diffusion layer 3, and the silicate glasses 8, 9, 10, 12 in FIG. 11 respectively correspond to the silicon substrate 16, the first diffusion layer 17, the second diffusion layer 18, and the silicate glasses 23, 24, 25, 27 in the fifth embodiment.

As a result of evaluating the current-voltage characteristics in each of the photovoltaic device (see FIG. 10) according to the fifth comparative example and the photovoltaic device (see FIG. 11) according to the fifth embodiment under AM 1.5 light illumination, the fifth embodiment has an open-circuit voltage of 2 mV higher and an fill factor of 0.005 higher than those of the fifth comparative example. The fifth comparative example has a current (leak current) of 1.2 A flowing in a direction opposite to the current-voltage characteristics during the application of a voltage of 10 V while the fifth embodiment has the current of 0.2 A, which shows a tendency of improvement.

As described above, the fifth embodiment can suppress the decreases in the open-circuit voltage and the fill factor or the occurrence of the current leak.

In addition, according to the present invention, the above preferred embodiments can be arbitrarily combined, or each preferred embodiment can be appropriately varied or omitted within the scope of the invention.

While the invention has been shown and described in detail, the foregoing description is in all aspects illustrative and not restrictive. It is therefore understood the numerous modifications and variations can be devised without departing from the scope of the invention.

### DESCRIPTION OF NUMERALS

1 silicon substrate; 2 first diffusion layer; 3 second diffusion layer; 4 first passivation film; 5 second passivation film; 6 first electrode; 7 second electrode; 8 to 12 silicate glass; 13 defect portion; 14 impurity diffusion layer; 15 impurity-concentration increasing portion; 16 silicon substrate; 17 first diffusion layer; 18 second diffusion layer; 19 first passivation film; 20 second passivation film; 21 first electrode; 22 second electrode; 23 to 26 silicate glass.

1: A method for manufacturing a photovoltaic device, comprising the steps of:
(a) forming a pyramidal texture on a first main surface of a silicon substrate;
(b) forming a first silicate glass that contains impurities of a first conductivity type on said first main surface;
(c) forming a second silicate glass that does not contain conductive impurities on said first silicate glass;
(d) diffusing the impurities of said first conductivity type contained in said first silicate glass to said first main surface of said silicon substrate;
(e) forming a third silicate glass that contains the impurities of said first conductivity type on said second silicate glass; and
(f) diffusing impurities of a second conductivity type to a second main surface opposite to said first main surface of said silicon substrate after said step (e).

2: The method for manufacturing a photovoltaic device according to claim 1, wherein in a case where a conductivity type of said silicon substrate is an n type, said first conductivity type is a p type and said second conductivity type is the n type.

3: The method for manufacturing a photovoltaic device according to claim 1, wherein in a case where a conductivity type of said silicon substrate is a p type, said first conductivity type is an n type and said second conductivity type is the p type.

4: The method for manufacturing a photovoltaic device according to claim 1, further comprising the step of (g) forming a fourth silicate glass that does not contain impurities imparting conductivity on said third silicate glass before said step (f).

5: The method for manufacturing a photovoltaic device according to claim 1, wherein said first silicate glass is formed by CVD in said step (b).

6: The method for manufacturing a photovoltaic device according to claim 1, further comprising the step of (h) removing said first silicate glass formed on said second main surface of said silicon substrate and said second silicate glass formed over said second main surface of said silicon substrate after said step (c).

7: The method for manufacturing a photovoltaic device according to claim 6, wherein said removing is performed with hydrofluoric acid in said step (h).

8: The method for manufacturing a photovoltaic device according to claim 1, wherein said third silicate glass is formed by sputtering in said step (e).

9: The method for manufacturing a photovoltaic device according to claim 4, wherein said fourth silicate glass is formed by sputtering in said step (g).

10: The method for manufacturing a photovoltaic device according to claim 1, wherein said third silicate glass is formed at an end portion of said silicon substrate in said step (e).

11: The method for manufacturing a photovoltaic device according to claim 4, wherein said fourth silicate glass is formed at an end portion of said silicon substrate in said step (g).
